(19) United States
(12) Patent Application Publication
(10) Pub. No.: US 2006/0076673 A1
(43) Pub. Date: Apr. 13, 2006

(54) Power amplifier module

(75) Inventors: Masayuki Miyaji, Kyoto (JP); Sadao Nagata, Osaka (JP); Hirotada Taniuchi, Hyogo (JP); Yorito Ota, Hyogo (JP); Takahiro Iwakiri, Osaka (JP); Tomotaka Sakatani, Kyoto (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/226,330

(22) Filed: Sep. 15, 2005

(30) Foreign Application Priority Data
Sep. 16, 2004 (JP) 2004-269537

(51) Int. Cl. H01L 23/34

(52) U.S. Cl. 257/707

(57) ABSTRACT

A semiconductor device has a plurality of external connection lead terminals including an input lead terminal, an output lead terminal, and an RF grounding lead terminal, a heat dissipation plate connected to the RF grounding lead terminal, a semiconductor device and a printed circuit board each mounted on the heat dissipation plate, and a mold resin for sealing the semiconductor device, the printed circuit board, and the heat dissipation plate such that at least a part of the back surface of the heat dissipation plate is exposed. The semiconductor device amplifies a signal inputted to the input lead terminal and outputs the amplified signal from the output lead terminal.

The present application claims priority under 35 U.S.C. § 119(a) to Japanese Patent Application JP 2004-269537, filed Sep. 16, 2004, the entire content of which is incorporated herein by reference.

### BACKGROUND OF THE INVENTION

1. Technical Field to Which the Invention Pertains

The present invention relates to a power amplifier module and, more particularly, to a power amplifier module used for a transmission power amplifier provided at a base station for mobile communication equipment or the like.

2. Prior Art

A power amplifier module has been used as a device composing a transmission power amplifier provided at a base station for mobile communication equipment. FIG. 12 is a view showing an example of the circuit structure of the transmission power amplifier provided at the base station for mobile communication equipment. FIG. 10A is a perspective view showing an example of the outer configuration of a conventional power amplifier module. FIG. 10B is a view showing an example of the structure of the conventional power amplifier module shown in FIG. 10A, from which a metal lid has been removed. FIG. 11 is a circuit diagram showing an example of the conventional power amplifier module.

As shown in FIG. 12, the transmission power amplifier provided at the base station is composed of amplifiers in, e.g., about three stages which are different in output power and connected in series. For example, the conventional transmission power amplifier comprises: a first-stage power amplifier 125 connected to an input terminal; a middle-stage power amplifier 126 for amplifying an output of the first-stage power amplifier 125; and a final-stage power amplifier 127 for amplifying an output of the middle-stage power amplifier 126.

In the conventional transmission power amplifier shown in FIG. 12, progressively higher output devices are used in the first, middle, and final stages. A power amplifier module is mostly used in a portion of which a requested saturation power is 30 W or less, such as the first-stage power amplifier 125. At present, frequencies in the 300- to 3000-MHz range are used as the frequencies of mobile communication equipment. However, as the frequencies of mobile communication equipment have become higher, the power amplifier module has been requested to perform an RF operation.

A description will be given to the structure of the conventional power amplifier module with reference to FIGS. 10A and 10B.

In the conventional power amplifier module, a printed circuit board 107 having passive elements, such as a resistor and a capacitor, mounted thereon is soldered onto a heat dissipation plate 105, while external connection lead terminals 102 protruding outwardly are attached onto a circuit pattern on the printed circuit board 107. Packaged semiconductor devices 114a and 114b are soldered directly onto the heat dissipation plate 105. Each of the semiconductor devices 114a and 114b is connected to the circuit pattern on the printed circuit board 107. To the power amplifier module, a metal lid 115 covering the upper surface of the printed circuit board 107 is attached in fit-in relation to the heat dissipation plate 105. Each of the metal lid 115 and the heat dissipation plate 105 is provided with depressed portions 130 for screwing the power amplifier module to an external heat dissipater or the like. The heat dissipation plate 105 dissipates heat generated in the packaged semiconductor devices 114a and 114b and also has an RF grounding function.

A description will be given to the circuit structure of the conventional power amplifier module.

In FIG. 11, each of an input circuit portion 110, an inter-stage circuit portion 112, and an output circuit portion 111 is composed of the printed circuit board 107.

The input circuit portion 110 is composed of the input matching circuit 116 and input bias circuit 117 of the first packaged (resin-sealed) semiconductor device 114a. The output circuit portion 111 is composed of the output matching circuit 123 and output bias circuit 124 of the second packaged semiconductor device 114b. The inter-stage circuit portion 112 is composed of the output matching circuit 118 and output bias circuit 119 of the first semiconductor device 114a, the input matching circuit 121 and input bias circuit 122 of the second semiconductor device 114b, and a DC blocking circuit 120 provided between the output matching circuit 118 and the input matching circuit 121. As the DC blocking circuit 120, a capacitor is used typically. As each of the input bias circuit and the output bias circuit, a capacitor having one end thereof RF grounded is typically attached onto the circuit pattern at a ¼-wavelength distance from the connection point with a main line through which a signal passes such that an impedance when a side with the bias circuits is viewed from a side with the main line (each of the matching circuits) is infinite.

There are cases where not only a power amplifier module but also a power amplifier oscillates when RF grounding becomes unstable. In the conventional power amplifier module, in particular, the RF grounding becomes unstable depending on the state of contact between the heat dissipation plate 105 and the metal lid 115.

To prevent the RF grounding from becoming unstable, a power amplifier module is disclosed in Japanese Laid-Open Patent Publication No. 2003-347444, which has achieved high stability by providing a part of the edges of the heat dissipation plate 105 with engaging means, providing a part of the side surfaces of the metal lid 115 with a hole, engaging the engaging means with the hole, and solder-bonding the metal lid 115 to the heat dissipation plate 105.

### SUMMARY OF THE INVENTION

In the power amplifier module disclosed in Japanese Laid-Open Patent Publication No. 2003-347444, however, a solder that has fixed the resistor, the capacitor, and the like onto the printed circuit board 107 may be melted when the metal lid 115 is solder-bonded to the heat dissipation plate 105. Consequently, these passive elements may be disconnected from the circuit pattern on the printed circuit board 107.

In the structure of the conventional power amplifier module, an opening 131 is formed disadvantageously between the external connection lead terminals 102 and the metal lid 115 shown in FIG. 10A and a foreign material made of metal may enter the power amplifier module through the opening 131 to cause an electric short circuit and thereby destroy the power amplifier module.

The problem of high cost is also encountered due to high material and processing costs for the heat dissipation plate 105, the metal lid 115, and the like and the complicated fabrication steps.

To solve the problems mentioned above, it is therefore an object of the present invention to provide a power amplifier module having a stable RF characteristic at low cost.

A power amplifier module according to the present invention comprises: a plurality of external connection lead terminals including an input lead terminal, an output lead terminal, and an RF grounding lead terminal; a heat dissipation plate connected to the RF grounding lead terminal; a semiconductor device and a printed circuit board each mounted on the heat dissipation plate; and a mold resin for sealing the semiconductor device, the printed circuit board, and the heat dissipation plate such that at least a part of a back surface of the heat dissipation plate is exposed, wherein a signal inputted to the input lead terminal is amplified and outputted from the output lead terminal.

In the power amplifier module, the semiconductor device and the printed circuit board are sealed with the resin without using a metal lid to cover the circuit portions so that RF grounding is provided more stably than in a conventional power amplifier module. In addition, processing cost can be reduced and material cost can be reduced as the size is reduced. Since an opening is not formed in the main body, an unwanted material from the outside the power amplifier module is prevented from entering the circuit portions so that it becomes possible to improve the reliability.

A plurality of the semiconductor devices are mounted on the heat dissipation plate. In the arrangement, if the output power of each of the semiconductor device is controlled properly, the input signal can be amplified effectively.

At least two or more of the plurality of semiconductor devices are formed on the same chip. The arrangement allows easier circuit adjustment because it can reduce variations in the electric properties of the chip compared with the case where the semiconductor devices are provided on different chips.

The N semiconductor devices (N is an integer of 2 or more) may be connected in series on the heat dissipation plate and the power amplifier module may further comprise: an input circuit portion which is provided in the printed circuit board and connected to the input lead terminal and outputs a signal to a first one of the semiconductor devices; (N−1) inter-stage circuit portions each of which is provided in the printed circuit board and interposed between each adjacent two of the N semiconductor devices; and an output circuit portion which is provided in the printed circuit board to receive a signal outputted from the N-th one of the N semiconductor devices and connected to the output lead terminal.

The input circuit portion may have a first input matching circuit which is connected to the input lead terminal and outputs a signal to the first one of the N semiconductor devices and a first input bias circuit which is connected to the first input matching circuit, each of the inter-stage circuit portions may have a first output matching circuit which receives an output of the one in a preceding stage of the N semiconductor devices, a first output bias circuit which is connected to the first output matching circuit, a second input matching circuit which outputs a signal to the one in a subsequent stage of the N semiconductor devices, a second input bias circuit which is connected to the second input matching circuit, and a DC blocking circuit which is interposed between the first output matching circuit and the second input matching circuit, and the output circuit portion may have a second output matching circuit which receives a signal outputted from the N-th one of the N semiconductor devices and is connected to the output lead terminal and a second output bias circuit which is connected to the second output matching circuit.

A capacitor is not provided in any of the first and second input bias circuits and the first and second output bias circuits. The arrangement allows a more significant size reduction in the module than in a conventional power amplifier module. In this case, the capacitor is provided on the external bias circuit of the power amplifier module.

The first input bias circuit, the first output bias circuit, the second input bias circuit, and the second output bias circuit may be connected individually to the plurality of external connection lead terminals except for the input lead terminal, the output lead terminal, and the RF grounding lead terminal.

Respective output powers of the N semiconductor devices are progressively larger with approach to the output lead terminal. The arrangement progressively amplifiers the output and allows an increase in power gain.

The input circuit portion has combined functions of adjusting an input impedance and supplying a voltage and is connected to the single input lead terminal. The arrangement can reduce the number of the external connection lead terminals compared with the case where the input matching circuit and the input bias circuit are connected individually to the different lead terminals.

The output circuit portion has combined functions of adjusting an output impedance and supplying a voltage and is connected to the single output lead terminal. The arrangement can reduce the number of the external connection lead terminals compared with the case where the output matching circuit and the output bias circuit are connected individually to the different lead terminals.

The only one semiconductor device is mounted on the heat dissipation plate and the power amplifier module further comprises: an input circuit portion which is provided in the printed circuit board and connected to the input lead terminal to output a signal to the semiconductor device; and an output circuit portion which is provided in the printed circuit board to receive an output of the semiconductor device and connected to the output lead terminal. The arrangement allows the semiconductor device to be increased in size and used preferably for a relatively high-output application or the like.

At least one RF grounding lead terminal is disposed between the input lead terminal and the output lead terminal. The arrangement can reduce the spatial coupling between the input signal and the output signal.

The mold resin may be molded into a polygonal configuration when viewed in two dimensions and the plurality of external connection lead terminals may be arranged within a range corresponding to a length of one edge of the polygonal configuration.

At least one of the plurality of external connection lead terminals may be disposed in opposing relation to the other external connection lead terminals.

Preferably, each of an impedance viewed from the input lead terminal and an impedance viewed from the output lead terminal is 50 Ω in terms of practical use.

### BRIEF DESCRIPTION OF THE DRAWINGS

FIG. 1A is a view showing an example of the structure of a power amplifier module according to a first embodiment of the present invention, from which a mold resin has been removed, and FIG. 1B is a view showing an example in which the power amplifier module according to the first embodiment is viewed from a side surface thereof;

FIG. 2 is a circuit diagram showing an example of the power amplifier module according to the first embodiment;

FIG. 3 is a view showing a power amplifier module according to the present invention and a capacitor disposed outside thereof;

FIG. 4 is a view showing an example of the structure of a power amplifier module according to a second embodiment of the present invention, from which a mold resin has been removed;

FIG. 5 is a circuit diagram showing an example of the power amplifier module according to the second embodiment;

FIG. 6 is a view showing an example in which three semiconductor devices are arranged in the power amplifier module according to the present invention;

FIG. 7 is a view showing an example of the structure of a power amplifier module according to a third embodiment of the present invention, from which a mold resin has been removed;

FIG. 8 is a circuit diagram showing an example of the power amplifier module according to the third embodiment;

FIG. 9 is a plan view showing a variation of the power amplifier module according to each of the embodiments of the present invention;

FIG. 10A is a perspective view showing an example of the outer configuration of a conventional power amplifier module and FIG. 10B is a view showing an example of the structure of the conventional power amplifier module shown in FIG. 10A, from which a metal lid has been removed;

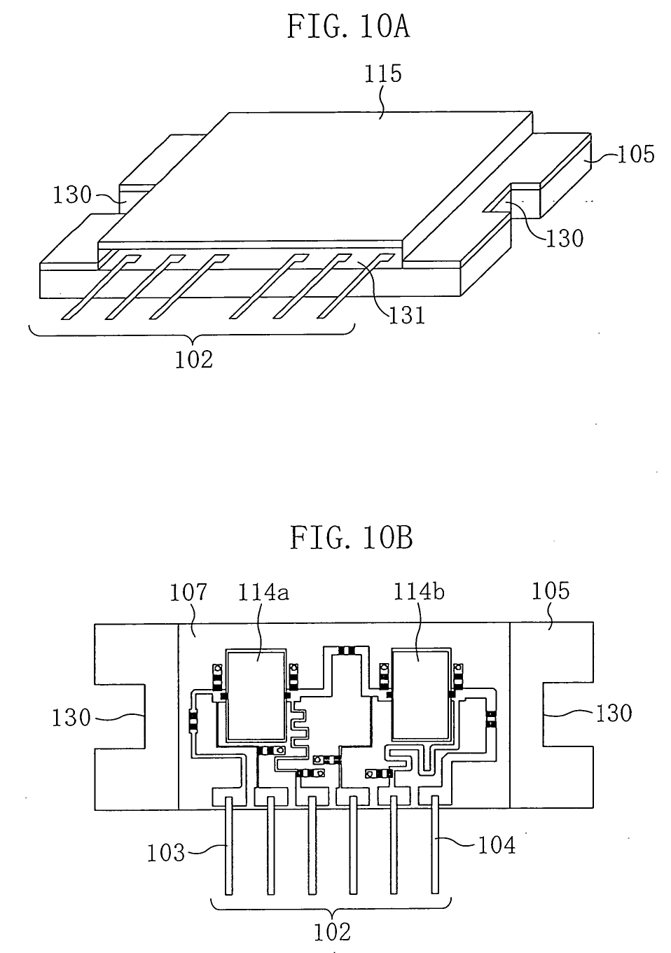

FIG. 11 is a circuit diagram showing an example of the conventional power amplifier module; and

FIG. 12 is a view showing an example of the structure of a transmission power amplifier provided at a base station for mobile communication equipment.

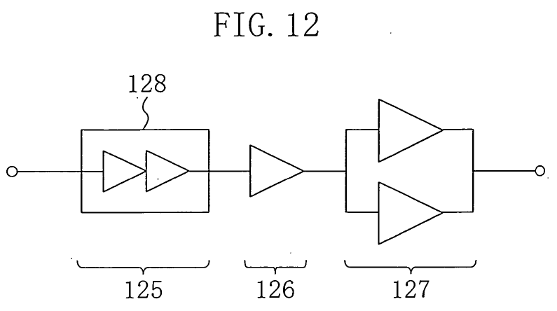

### DESCRIPTION OF THE PREFERRED EMBODIMENTS

### Embodiment 1

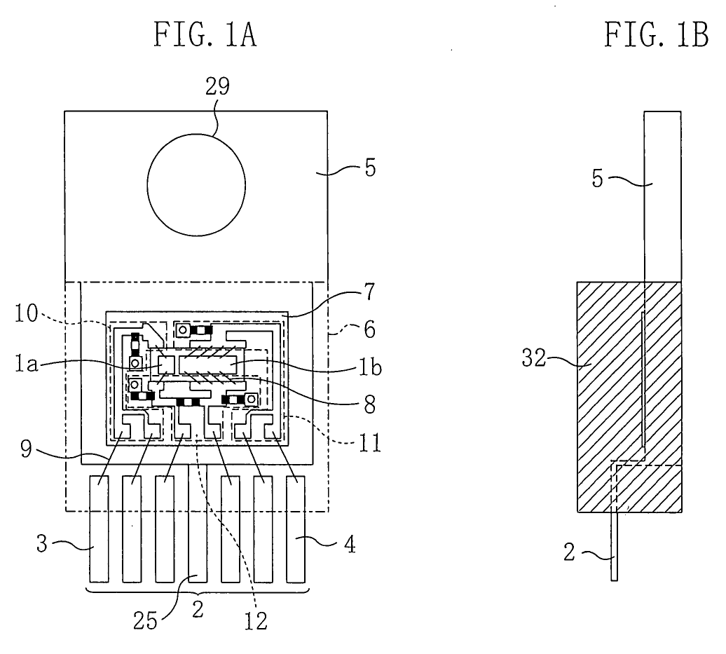

FIG. 1A is a view showing an example of the structure of a power amplifier module according to a first embodiment of the present invention, from which a mold resin has been removed. FIG. 1B is a view showing an example in which the power amplifier module according to the first embodiment is viewed from a side surface thereof. The power amplifier module according to the first embodiment has the function of amplifying a signal inputted to an input lead terminal 3 and outputting the amplified signal from an output lead terminal 4.

As shown in FIGS. 1A and 1B, the power amplifier module comprises: a plurality of external connection lead terminals 2 including the input lead terminal 3, the output lead terminal 4, and an RF grounding lead terminal 25; a heat dissipation plate 5 connected to the RF grounding lead terminal 25; first and second semiconductor devices 1a and 1b mounted on the heat dissipation plate 5; a printed circuit board 7 mounted on the heat dissipation plate 5; and a mold resin 32 for sealing the first and second semiconductor devices 1a and 1b and the printed circuit board 7. Each of the first and second semiconductor devices 1a and 1b is provided with a large number of active elements (such as transistors). The first and second semiconductor devices 1a and 1b are formed separately on different semiconductor chips. The mold resin 32 seals a part of the heat dissipation plate 5 such that at least a part of the back surface of the heat dissipation plate 5 is exposed. The portion defined by the dotted rectangle shown in FIG. 1A is a resin molded region 6. One of the characteristics of the power amplifier module according to the present embodiment is that the first and second semiconductor devices 1a and 1b and the printed circuit board 7 are molded with a resin. The operation and effect of the characteristic will be described later.

For example, seven external connection lead terminals 2 are arranged in the same direction, of which the center one is connected as the RF grounding lead terminal 25 to the heat dissipation plate 5. Preferably, the input lead terminal 3 and the output lead terminal 4 are positioned in maximally spaced apart relation for the avoidance of the spatial coupling therebetween. When the post-molding configuration is a quadrilateral (or a polygon), as shown in FIG. 1A, and the external connection lead terminals 2 are arranged within a range corresponding to the length of one edge of the quadrilateral (polygon), e.g., the input lead terminal 3 is provided at one end portion of the edge and the output lead terminal 4 is provided at the other end of the edge.

In the portion of the heat dissipation plate 5 which is not sealed with the resin, a hole 29 for connecting the power amplifier module to an external heat dissipater or the like is provided. The printed circuit board 7 has been formed with an input circuit portion 10, an inter-stage circuit portion 12, and an output circuit portion 11, of which the specific circuit structures will be described herein below.

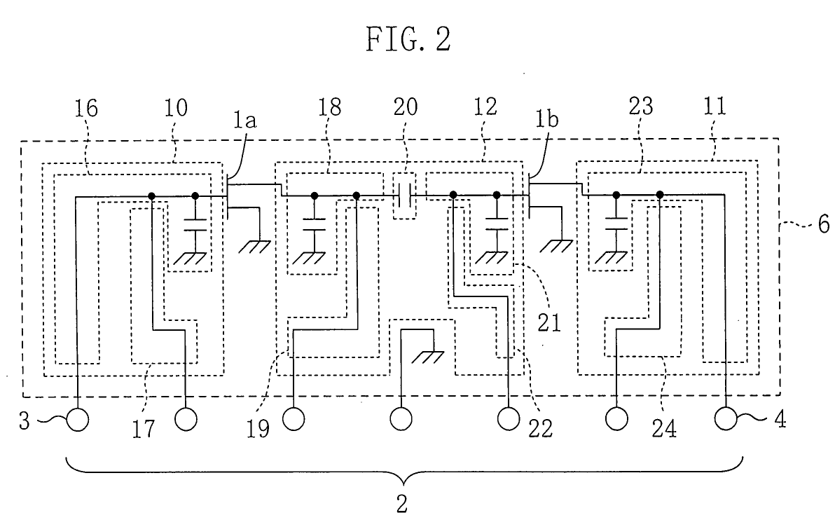

FIG. 2 is a circuit diagram showing an example of the power amplifier module according to the first embodiment. As shown in the drawing, the input circuit portion 10 receives an input signal from outside the module and outputs a signal to the first semiconductor device 1a. An output of the first semiconductor device 1a is inputted to the inter-stage circuit portion 12. An output of the inter-stage circuit portion 12 is inputted to the second semiconductor device 1b. An output of the second semiconductor device 1b is inputted to the output circuit portion 11 such that an amplified signal is outputted from the output lead terminal 4 connected to the output circuit portion 11.

The input circuit portion 10 is composed of the input matching circuit 16 and input bias circuit 17 of the first semiconductor device 1a. The output circuit portion 11 is composed of the output matching circuit 23 and output bias circuit 24 of the second semiconductor device 1b. The input matching circuit 16 and the output matching circuit 23 are for controlling an input impedance viewed from the input lead terminal and an output impedance viewed from the output lead terminal such that they have specified values. Each of the input matching circuit 16 and the output matching circuit 23 is composed of a capacitor interposed between a signal path and the ground. If the power amplifier module is for use at the base station, the input/output impedance is normally set to 50 Ω and the capacitance of the capacitor is mostly 5 pF or less.

The inter-stage circuit portion 12 is composed of the output matching circuit 18 and output bias circuit 19 of the first semiconductor device 1a, the input matching circuit 21 and input bias circuit 22 of the second semiconductor device 1b, and a DC blocking circuit 20 provided between the output matching circuit 18 and the input matching circuit 21. In general, the DC blocking circuit 20 has a capacitor. In this case, a capacitor with a capacitance of about 10 pF to 100 pF is used in most cases.

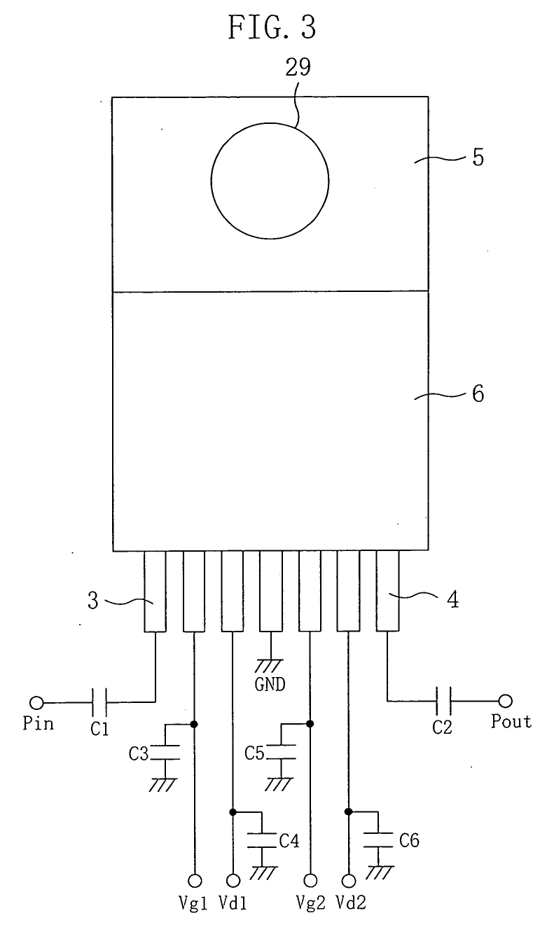

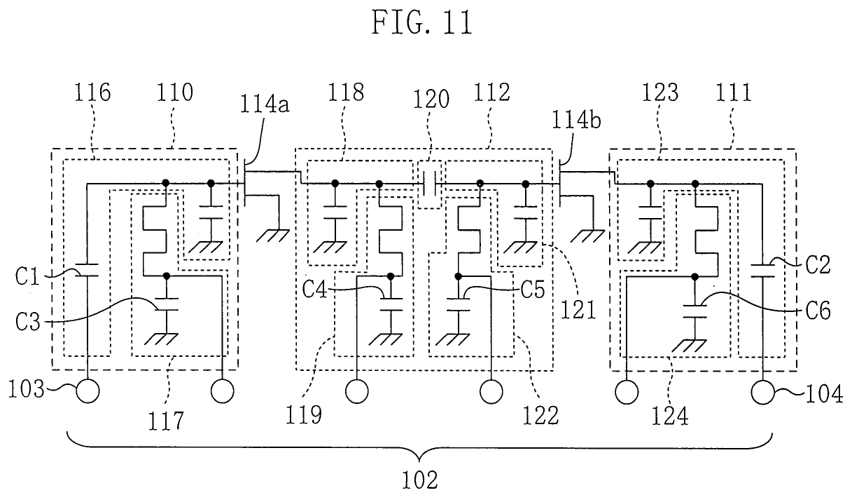

FIG. 3 is a view showing an example of capacitors to be disposed externally of the power amplifier module according to the present embodiment when the power amplifier module is used. From a comparison between FIGS. 2 and 3 and FIG. 11, it will be understood that capacitors C1 to C6 are provided externally of the power amplifier module according to the present embodiment, in contrast to the conventional power amplifier module in which the input matching circuit 116 is provided with the DC blocking capacitor C1, the output matching circuit 123 is provided with the DC blocking capacitor C2, and the bias circuits are provided with the capacitors C3 to C6 each of which has one end thereof RF grounded and is mounted on the circuit pattern at a distance of ¼ of the wavelength of an input signal from the main line (each of the matching circuits) through which the signal passes. In addition, the input bias circuit 17, the output bias circuit 19, the input bias circuit 22, and the output bias circuit 24 are connected individually to the external connection lead terminals 2 other than the input lead terminal 3, the output lead terminal 4, and the RF grounding lead terminal 25. A wiring path from each of the bias circuits to the external connection lead terminal 2 connected thereto has no capacitor provided thereon so that it is composed of a shortest line. Accordingly, the power amplifier module according to the present embodiment can be reduced significantly in size compared with the conventional power amplifier module. In FIG. 3, Pin denotes an input portion, Pout denotes an output portion, Vg1 denotes the input bias portion of the first semiconductor device, Vd1 denotes the output bias portion of the first semiconductor device, Vg2 denotes the input bias portion of the second semiconductor device, and Vd2 denotes the output bias portion of the second semiconductor device.

A brief description will be given next to a method for fabricating the power amplifier module according to the present embodiment.

First, passive elements such as a resistor and a capacitor are mounted on the printed circuit board 7 as necessary. Then, the first and second semiconductor devices 1a and 1b and the printed circuit board 7 are bonded onto the heat dissipation plate 5 by soldering or by using a conductive adhesive agent. Subsequently, the input circuit portion 10 and the input portion of the first semiconductor device 1a are connected to each other by using a bonding wire 8. At this time, the input circuit portion 10 and the input portion of the first semiconductor device 1a are connected more preferably in an RF manner. Likewise, the input circuit portion 10 and the input lead terminal 3 are also connected to each other in an RF manner by using a metal wire 9. The wording “connected to each other in an RF manner” used herein indicates that an RF signal is allowed to pass with a minimum loss.

Next, the output circuit portion 11 and the output portion of the second semiconductor device 1b are connected in an RF manner by using the bonding wire 8. On the other hand, the output circuit portion 11 and the output lead terminal 4 are connected in an RF manner by using the metal wire 9.

Next, the inter-stage circuit portion 12 and the output portion of the first semiconductor device 1a are connected in an RF manner by using the bonding wire 8. On the other hand, the inter-stage circuit portion 12 and the input portion of the second semiconductor device 1b are connected in an RF manner by using the bonding wire 8. Further, one end of the input bias circuit 17 which is not connected to the input matching circuit 16 is connected electrically to the unconnected one of the external connection lead terminals 2 by using the metal wire 9. The wording “connected electrically” used herein indicates that a current flows.

Thereafter, the output bias circuit 19, the input bias circuit 22, and the output bias circuit 24 are connected electrically individually to the unconnected ones of the external connection lead terminals 2 by using the metal wires 9. Then, resin molding is performed by using the mold resin 32 such that at least a part of the back surface of the heat dissipation plate 5 is exposed. The power amplifier module according to the present embodiment can thus be fabricated but the order in which the bonding wires 8 and the metal wires 9 are strung may also be reversed.

Since sealing with the mold resin 32 has thus been performed in the power amplifier module according to the present embodiment, the metal lid used in the conventional power amplifier module and a solder for adhering the metal lid are no more necessary. As a result, it becomes possible to stably provide RF grounding. Since the proximal end portion of the external connection lead terminal is also sealed with the mold resin, a foreign material is prevented from entering the circuit portions so that a stable RF characteristic is obtainable.

Since the power amplifier module can further be reduced in size than the conventional power amplifier module by providing the external capacitors connected to the bias circuits or the external capacitors connected to the input matching circuits and the output matching circuits, it can contribute to the size reduction of the entire communication equipment.

Since material and processing costs for the power amplifier module according to the present embodiment can be reduced by sealing the minimum structure thereof, a significant reduction in fabrication cost has been achieved.

Although the description has been given thus far to the power amplifier module in which the center one of the external connection lead terminals 2 is composed of the RF grounding lead terminal 25 conncted to the heat dissipation plate 5, the structure of the power amplifier according to the present embodiment is not limited thereto. It is also possible to connect those of the external connection lead terminals 2 other than the center one to the heat dissipation plate 5. Alternatively, the plurality of lead terminals may also be connected to the heat dissipation plate 5.

Although the description has been given thus far to the example in which the two semiconductor devices are provided in the signal path extending from the input lead terminal 3 to the output lead terminal 4, it is also possible to provide only one semiconductor device or three or more semiconductor devices instead. In the case where the two or more semiconductor devices are arranged, the semiconductor devices containing respective transistors having progressively higher outputs with distance from the input lead terminal 3 toward the output lead terminal 4 may be provided appropriately.

### Embodiment 2

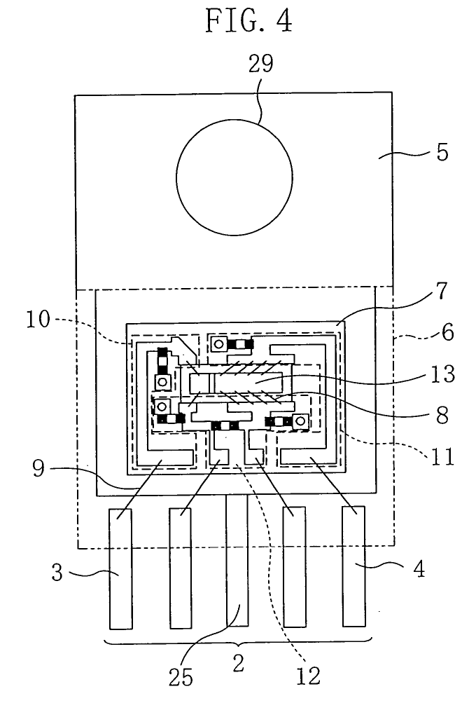

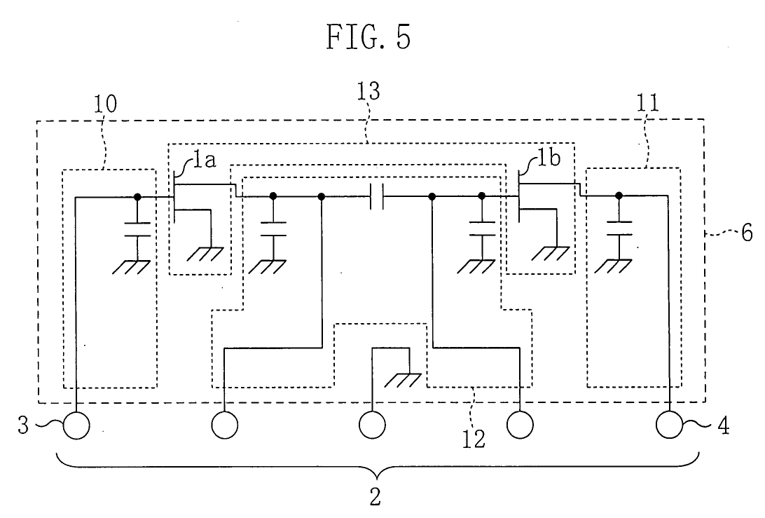

FIG. 4 is a view showing an example of the structure of a power amplifier module according to a second embodiment of the present invention, from which a mold resin has been removed. FIG. 5 is a circuit diagram showing an example of the power amplifier module according to the second embodiment.

In the power amplifier module according to the second embodiment, the first and second semiconductor devices 1a and 1b mounted on the power amplifier module according to the first embodiment are provided on the same semiconductor chip 13. When viewed from above, the five external connection lead terminals 2 are arranged within a range corresponding to the length of one edge of the mold resin and extending in the same direction. The center one of the external connection lead terminals 2 serves as the RF grounding lead terminal 25 connected to the heat dissipation plate 5. As for the other members shown in FIG. 4 which are the same as used in the power amplifier module according to the first embodiment shown in FIGS. 1 and 2, the description thereof will be omitted by retaining the same reference numerals in FIGS. 4 and 5.

As shown in FIG. 4, in the power amplifier module according to the present embodiment, the input lead terminal 3 and the input bias lead terminal (the external connection lead terminal connected to the input bias circuit) of the first semiconductor device 1a are formed as one common terminal, while the output lead terminal 4 and the output bias lead terminal of the second semiconductor device 1b are formed as one common terminal. In other words, in the power amplifier module according to the second embodiment, the input matching circuit and input bias circuit of the first semiconductor device 1a in the power amplifier module according to the first embodiment are formed as a common circuit, while the output matching circuit and output bias circuit of the second semiconductor device 1b are formed as a common circuit.

The input lead terminal 3 and the output lead terminal 4 are positioned as the both-end ones of the five external connection lead terminals 2 to prevent the occurrence of interference or the like between an input signal and an output signal. The external connection lead terminal 2 between the input lead terminal 3 and the RF grounding lead terminal 25 is connected electrically to the output bias circuit of the first semiconductor device 1a by using the metal wire 9. The external connection lead terminal 2 between the output lead terminal 4 and the RF grounding lead terminal 25 is connected electrically to the input bias circuit of the second semiconductor device 1b by using the metal wire 9.

A description will be given herein below to an advantage provided by forming the semiconductor devices on the same semiconductor chip in the power amplifier module according to the present embodiment.

The same voltage is supplied from outside the power amplifier module to each of the input bias circuit of the first semiconductor device 1a and the input bias circuit of the second semiconductor device 1b. A consideration will be given herein to the case where a current of 200 mA and a current of 800 mA are caused to flow in the first and second semiconductor devices 1a and 1b, respectively. At this time, the voltage supplied from outside the module is designated as V1.

If the first and second semiconductor devices 1a and 1b are provided on different chips that have been sliced from different wafers, even though the same voltage V1 is supplied, there are cases where a current of 200 mA flows in the first semiconductor device 1a and a current of only 720 mA flows in the second semiconductor device 1b and where a current of 180 mA flows in the first semiconductor device 1a and a current of 800 mA flows in the second semiconductor device 1b. Thus, variations from the set values of the currents flowing in the individual semiconductor devices are large and a ratio (1:4) between the currents flowing in the individual semiconductor devices is not constant. This is because the state of diffusion and influences exerted by other processes differ from one wafer to another.

By contrast, if the semiconductor devices are provided on the same semiconductor chip, the ratio (1:4) between the respective currents flowing in the individual semiconductor devices becomes constant and the currents can be set to specified values by changing the voltage supplied from outside the module from V1 to V2.

Thus, in the power amplifier module according to the present embodiment, an error between the respective currents flowing in the first and second semiconductor devices 1a and 1b can be reduced and therefore a power amplifying operation can be performed as has been set.

Since the input lead terminal 3 and the input bias lead terminal of the first semiconductor device 1a are formed as the one common terminal and the output lead terminal 4 and the output bias lead terminal of the second semiconductor device 1b are formed as the one common terminal in the example shown in FIG. 5, the number of the external connection leads can be reduced and a circuit area can be reduced.

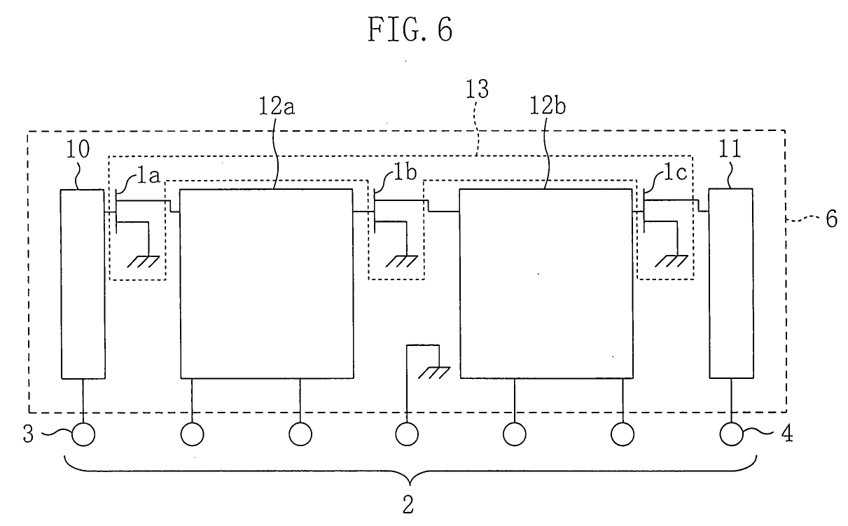

FIG. 6 is a view showing an example in which three semiconductor devices (the first semiconductor device 1a, the second semiconductor device 1b, and a third semiconductor device 1c) are arranged in the power amplifier module according to the present embodiment. Although the description has been given thus far to the power amplifier module which uses the two semiconductor devices, the structure of the power amplifier module according to the present embodiment is not limited thereto. The power amplifier module according to the present embodiment may also use the three semiconductor devices connected in series, as shown in FIG. 6. In this case, an additional inter-stage circuit portion may be provided appropriately between the second and third semiconductor devices 1b and 1c. It is also possible to use four or more semiconductor devices.

### Embodiment 3

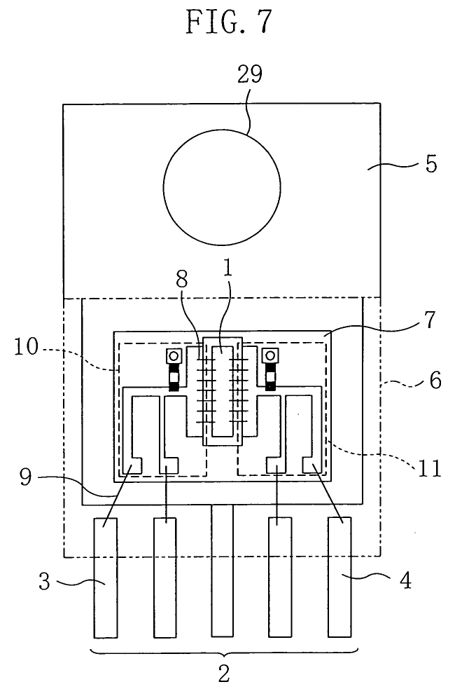

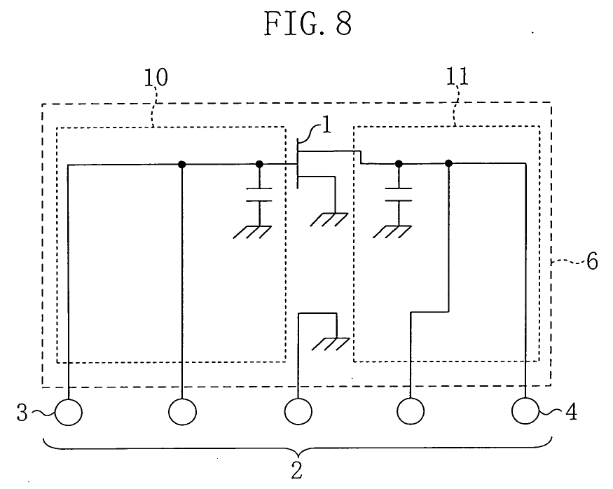

FIG. 7 is a view showing an example of the structure of a power amplifier module according to a third embodiment of the present invention, from which a mold resin has been removed. FIG. 8 is a circuit diagram showing an example of the power amplifier module according to the third embodiment.

The power amplifier module according to the third embodiment has been obtained by reducing the number of the semiconductor devices to one in the power amplifier module according to the first embodiment.

In this case, only the input circuit portion 10 and the output circuit portion 11 are provided in the printed circuit board 7. The number of the external connection lead terminals 2 composing the power amplifier module according to the third embodiment can also be set to 5.

If the input lead terminal 3 and the input bias lead terminal of the semiconductor device 1 are formed as a common terminal and the output lead terminal 4 and the output bias lead terminal of the semiconductor device 1 are formed as a common terminal in the same manner as in the power amplifier module according to the second embodiment, the power amplifier module according to the third embodiment can be composed of three external connection lead terminals 2.

The power amplifier module according to the present embodiment is used preferably in the case where a semiconductor device produces a large output power, such as the second semiconductor device 1b of the power amplifier module according to each of the first and second embodiments.

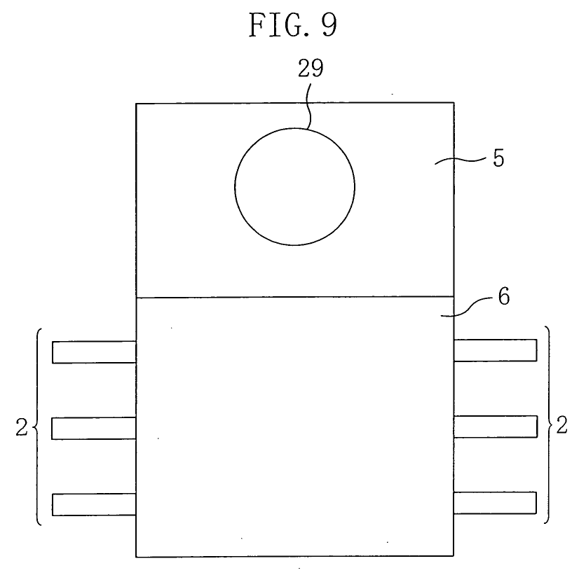

FIG. 9 is a plan view showing a variation of the power amplifier module according to each of the embodiments of the present invention. In each of the first to third embodiments, the description has been given to the structure of the power amplifier module in which the external connection lead terminals 2 are arranged within a range corresponding to the length of the same edge and extending in the same direction. However, it is also possible to arrange the external connection lead terminals such that at least one thereof is in opposing relation to the other external connection lead terminals when viewed from above, as shown in FIG. 9. In this case, it is preferable to use one of the three external connection lead terminals 2 provided within a range corresponding to the length of one of the opposing edges as the RF grounding lead terminal and arrange the input lead terminal and the output lead terminal within a range corresponding to the length of the other of the opposing edges.

Thus, since the power amplifier module according to the present invention can be provided with a stable characteristic, in a small size, and at low cost, it can be used for an application which power amplifiers an extremely weak signal and outputs the power amplified signal, as in a transmission power amplifier provided at a base station for mobile communication equipment.

What is claimed is:

1. A power amplifier module comprising:
a plurality of external connection lead terminals including an input lead terminal, an output lead terminal, and an RF grounding lead terminal;
a heat dissipation plate connected to the RF grounding lead terminal;
a semiconductor device and a printed circuit board each mounted on the heat dissipation plate; and
a mold resin for sealing the semiconductor device, the printed circuit board, and the heat dissipation plate such that at least a part of a back surface of the heat dissipation plate is exposed, wherein
a signal inputted to the input lead terminal is amplified and outputted from the output lead terminal.

2. The power amplifier module of claim 1, wherein a plurality of the semiconductor devices are mounted on the heat dissipation plate.

3. The power amplifier module of claim 2, wherein at least two or more of the plurality of semiconductor devices are formed on the same chip.

4. The power amplifier module of claim 1, wherein the N semiconductor devices (N is an integer of 2 or more) are connected in series on the heat dissipation plate, the power amplifier module further comprising:
an input circuit portion which is provided in the printed circuit board and connected to the input lead terminal and outputs a signal to a first one of the semiconductor devices;
(N−1) inter-stage circuit portions each of which is provided in the printed circuit board and interposed between each adjacent two of the N semiconductor devices; and
an output circuit portion which is provided in the printed circuit board to receive a signal outputted from the N-th one of the N semiconductor devices and connected to the output lead terminal.

5. The power amplifier module of claim 4, wherein
the input circuit portion has a first input matching circuit which is connected to the input lead terminal and outputs a signal to the first one of the N semiconductor devices and a first input bias circuit which is connected to the first input matching circuit,
each of the inter-stage circuit portions has a first output matching circuit which receives an output of the one in a preceding stage of the N semiconductor devices, a first output bias circuit which is connected to the first output matching circuit, a second input matching circuit which outputs a signal to the one in a subsequent stage of the N semiconductor devices, a second input bias circuit which is connected to the second input matching circuit, and a DC blocking circuit which is interposed between the first output matching circuit and the second input matching circuit, and
the output circuit portion has a second output matching circuit which receives a signal outputted from the N-th one of the N semiconductor devices and is connected to the output lead terminal and a second output bias circuit which is connected to the second output matching circuit.

6. The power amplifier module of claim 5, wherein a capacitor is not provided in any of the first and second input bias circuits and the first and second output bias circuits.

7. The power amplifier module of claim 5, wherein the first input bias circuit, the first output bias circuit, the second input bias circuit, and the second output bias circuit are connected individually to the plurality of external connection lead terminals except for the input lead terminal, the output lead terminal, and the RF grounding lead terminal.

8. The power amplifier module of claim 4, wherein respective output powers of the N semiconductor devices are progressively larger with approach to the output lead terminal.

9. The power amplifier module of claim 4, wherein the input circuit portion has combined functions of adjusting an input impedance and supplying a voltage and is connected to the single input lead terminal.

10. The power amplifier module of claim 4, wherein the output circuit portion has combined functions of adjusting an output impedance and supplying a voltage and is connected to the single output lead terminal.

11. The power amplifier module of claim 1, wherein
the only one semiconductor device is mounted on the heat dissipation plate, the power amplifier module further comprising:
an input circuit portion which is provided in the printed circuit board and connected to the input lead terminal to output a signal to the semiconductor device; and
an output circuit portion which is provided in the printed circuit board to receive an output of the semiconductor device and connected to the output lead terminal.

12. The power amplifier module of claim 1, wherein the at least one RF grounding lead terminal is disposed between the input lead terminal and the output lead terminal.

13. The power amplifier module of claim 12, wherein
the mold resin is molded into a polygonal configuration when viewed in two dimensions and
the plurality of external connection lead terminals are arranged within a range corresponding to a length of one edge of the polygonal configuration.

14. The power amplifier module of claim 1, wherein at least one of the plurality of external connection lead terminals is disposed in opposing relation to the other external connection lead terminals.

15. The power amplifier module of claim 1, wherein each of an impedance viewed from the input lead terminal and an impedance viewed from the output lead terminal is 50 Ω.
